(19) United States
(12) Patent Application Publication
(10) Pub. No.: US 2011/0017294 A1
(43) Pub. Date: Jan. 27, 2011

(54) PACKAGE FOR SOLAR CELL CHIP

(75) Inventors: TAI-CHERNG YU, Tu-Cheng (TW); YUNG-LUN HUANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/833,340

(22) Filed: Jul. 9, 2010

(30) Foreign Application Priority Data
Jul. 21, 2009 (CN) 200910304584.0

(51) Int. Cl. H01L 31/0232

(52) U.S. Cl. 136/259

(57) ABSTRACT

A solar cell package comprises a ceramic substrate, a light-electricity transformation unit provided on the substrate for transforming solar energy into electricity, and a sealing component covering the light-electricity transformation unit and the ceramic substrate. A Fresnel lens is disposed corresponding to the top of the light-electricity transformation unit, converges and concentrates solar energy onto the light-electricity transformation unit.

### BACKGROUND

1. Technical Field

The present application is related to a solar cell device, and especially to a package of a solar cell chip.

2. Description of Related Art

Nowadays, with the resources on the earth being depleted day by day, the cost of investment for energy increases significantly. Solar energy has drawn attention from the energy industry as an alternative source of energy, and found widespread applications in a variety of fields.

Solar cells are usually packed and realized as semiconductor devices. During operation of such semiconductor devices, temperature of semiconductor devices increases due to heat created by solar cells. Therefore, operation efficiency of the semiconductor devices for solar cells will decrease.

A solar cell is conventionally integrated on a substrate, and a metal plate is soldered on the substrate for dissipating heat created by the solar cell. However, the heat dissipation plate is costly, and does not provide efficient heat dissipation.

### BRIEF DESCRIPTION OF THE DRAWINGS

FIG. 1 is a schematic drawing showing an exemplary embodiment of a package for solar cell chip illustrated by the present application.

FIG. 2 is a schematic drawing showing another exemplary embodiment of a package for solar cell chip illustrated by the present application.

### DETAILED DESCRIPTION

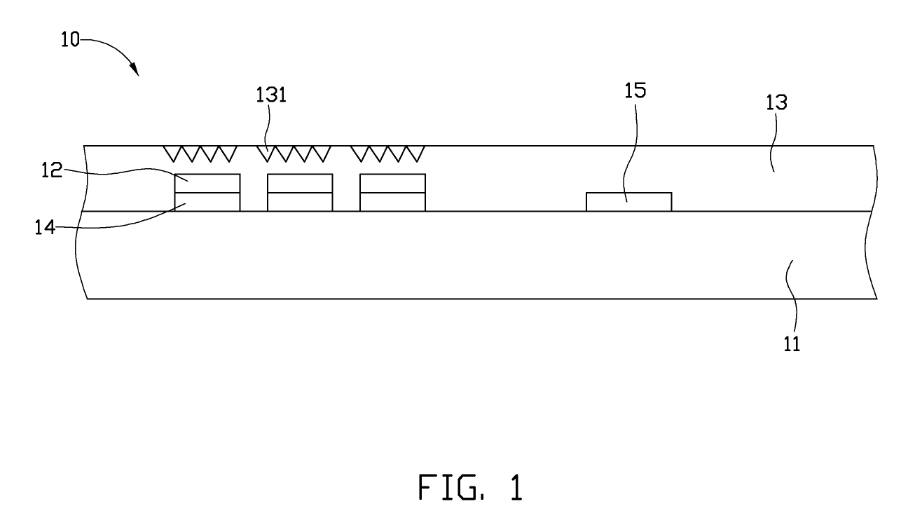

Referring to FIG. 1, a solar cell package 10 comprises a ceramic substrate 11, a plurality of light-electricity transforming units 12, a package component 13, an adhesive layer 14, and a circuit unit 15. In one exemplary non-limiting embodiment, the size of each light-electricity transformation unit 12 is larger than about one square millimeter (mm²), and is less than about nine square millimeters. The light-electricity transformation units transform light into electricity. The circuit unit 15 is positioned on the ceramic substrate 11 by the adhesive layer 14, and is electrically connected to the light-electricity transformation units 12 for outputting electricity. The light-electricity transformation units 12 can be arranged as arrays on the substrate 11.

In one example, the light-electricity transformation units 12 can be solar cell chips, for example, a solar cell chip made of Group III-V compounds. The Group III-V compounds include gallium nitride (GaN), gallium arsenide (GaAs), gallium antimonide (GaSb), or indium phosphide (InP).

Material of the package component 13 can be selected from the group consisting of polydimethylsiloxane (PDMS), polyepoxide (epoxy), and polymethyl methacrylate (PMMA). The package component 13 covers the ceramic substrate and the solar cell chips 12, and patterns 131 are formed at positions on the package component 13 corresponding to the positions of the solar cell chips 12. The package component 13 prevents moisture from penetrating to the solar cell chips 12 and the circuit unit 15 on the ceramic substrate 11 causing short circuits, like water drops.

The inclusion of patterns causes the incident angle of light therethrough to be relatively smaller. Furthermore, the patterns 131 could be Fresnel lenses, which are structured and arranged to concentrate light onto the light-transforming units and reduce energy loss.

Because the coefficient of thermal expansion of ceramics is similar to the coefficient of thermal expansion of group III-V compounds mentioned above, the performance of the solar cell package 10 is not easily affected by thermal expansion when the temperature increases. Compared to metal substrates, ceramic has better tolerance to acid and alkali. Ceramic also has excellent thermal conductivity to prevent overheating. Furthermore, manufacturing ceramic substrates is less costly than manufacturing metal substrates.

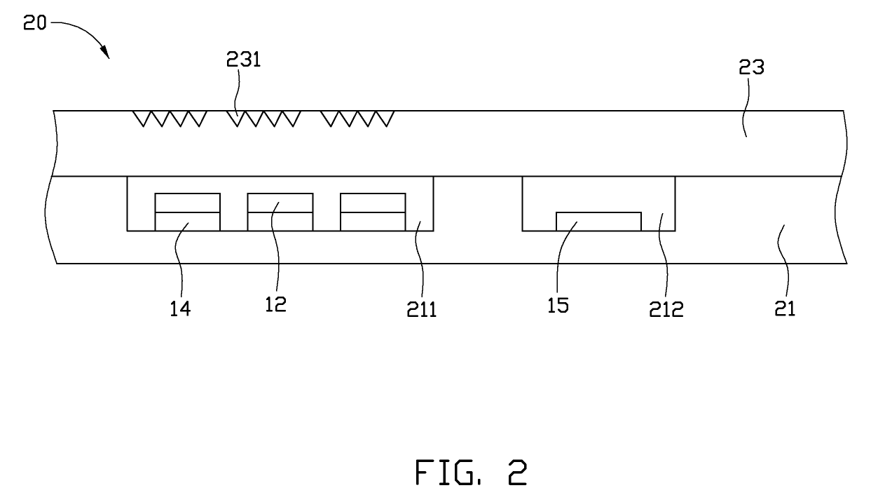

As shown in FIG. 2, the solar cell package 20 of the second embodiment is similar to the solar cell package 10, and differs in a first receiving cavity 211 and a second receiving cavity 212, provided on a substrate 21. The solar cell chip 12 is positioned inside the first receiving cavity 211, and fixed by the adhesive layer 14. The circuit unit 15 is provided inside the second receiving cavity 212. The Fresnel lens 231 is positioned above the location of the solar cell chips 12, and the numbers of the Fresnel lens 231 correspond to the numbers of the solar cell chip 12.

While the disclosure has been described by way of example and in terms of preferred embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell package, comprising:
a ceramic substrate;
a light-electricity transformation unit provided on the substrate for transforming solar energy into electricity;
a sealing component covering the light-electricity transformation unit and the ceramic substrate;
a pattern provided on the sealing component, disposed corresponding to top of the light-electricity transformation unit, to converge and concentrate the solar energy onto the light-electricity transformation unit.

2. The solar cell package as claimed in claim 1, wherein the pattern is formed as a Fresnel lens.

3. The solar cell package as claimed in claim 1, wherein a cavity is defined on the substrate for receiving the light-electricity transformation unit.

4. The solar cell package as claimed in claim 1, wherein the light-electricity transformation unit is fastened on the substrate by an adhesive.

5. The solar cell package as claimed in claim 1, wherein a circuit unit is provided on the substrate for outputting electricity transformed by the light-electricity transformation unit.

6. The solar cell package as claimed in claim 1, wherein the light-electricity transformation unit is made of group III-V compounds.

7. The solar cell package as claimed in claim 6, wherein the light-electricity transformation unit is made of one or more compounds selected from a group consisting of: GaN, GaAs, GaSb, and InP.

8. A solar cell package, comprising:
a ceramic substrate;
a light-electricity transformation unit provided on the substrate for transforming solar energy into electricity;
a sealing component covering the light-electricity transformation unit and the ceramic substrate, wherein a pattern provided on the sealing component is structured and arranged so as to converge and concentrate the solar energy onto the light-electricity transformation unit, the pattern disposed corresponding to top of the light-electricity transformation unit.
